(19) United States
(12) Patent Application Publication
(10) Pub. No.: US 2016/0285281 A1
(43) Pub. Date: Sep. 29, 2016

(54) STATE OF CHARGE DETECTING DEVICE, STATE OF CHARGE DETECTING METHOD, STATE OF CHARGE DETECTING SYSTEM, AND BATTERY PACK

(71) Applicant: ROHM CO., LTD., Ukyo-ku (JP)

(72) Inventor: Takahiro SHIMIZU, Ukyo-ku (JP)

(21) Appl. No.: 15/075,863

(22) Filed: Mar. 21, 2016

(30) Foreign Application Priority Data
Mar. 26, 2015 (JP) 2015-064322

(51) Int. Cl. H02J 7/00; G01R 31/36

(52) U.S. Cl. CPC H02J 7/007; G01R 31/3624; G01R 31/3651

(57) ABSTRACT

A state of charge (SOC) detecting device includes a voltage monitor part connected to a battery and configured to monitor a voltage of the battery; a current monitor part connected to the battery and configured to monitor a current of the battery; an SOC calculation part configured to calculate an SOC of the battery by using any one or both of the voltage value monitored by a voltage monitor part and a current value monitored by the current monitor part; and an SOC conversion part configured to convert the SOC calculated by the SOC calculation part such to delay a change in SOC depending on a load of the battery.

### CROSS-REFERENCE TO RELATED APPLICATION

This application is based upon and claims the benefit of priority from Japan Patent Applications No. 2015-064322, filed on Mar. 26, 2015, the entire contents of which are incorporated herein by reference.

### TECHNICAL FIELD

The present disclosure relates to a state of charge (SOC) detecting device, an SOC detecting method, an SOC detecting system, and a battery pack.

### BACKGROUND

A state of charge (SOC) is used as an indicator indicating an SOC of a secondary battery such as a lithium ion battery. As a means for managing a residual capacity using such SOC, for example, a device for estimating a battery capacity at a predetermined time has been disclosed.

An SOC, which indicates a ratio of a charged quantity of electricity to an electric capacity, is calculated, for example, based on a measurement of a battery voltage or the like but has a problem in that it cannot be precisely calculated when a quantity of electricity (electric charge: Coulomb) of a load is changed.

### SUMMARY

The present disclosure provides some embodiments of an SOC detecting device, an SOC detecting method, an SOC detecting system, and a battery pack, which can detect and notify a smooth SOC which fluctuates less even when an electric charge of a load is changed.

According to one embodiment of the present disclosure, there is provided a state of charge (SOC) detecting device including: a voltage monitor part connected to a battery and configured to monitor a voltage of the battery; a current monitor part connected to the battery and configured to monitor a current of the battery; an SOC calculation part configured to calculate an SOC of the battery by using any one or both of a voltage value monitored by the voltage monitor part and a current value monitored by the current monitor part; and an SOC conversion part configured to convert the SOC calculated by the SOC calculation part to delay a change in SOC depending on a load of the battery.

According to another embodiment of the present disclosure, there is provided a battery pack, including: a battery; and a state of charge (SOC) detecting device, wherein the SOC detecting device includes: a voltage monitor part connected to the battery and configured to monitor a voltage of the battery; a current monitor part connected to the battery and configured to monitor a current of the battery; an SOC calculation part configured to calculate an SOC of the battery by using any one or both of a voltage value monitored by the voltage monitor part and a current value monitored by the current monitor part; and an SOC conversion part configured to convert the SOC calculated by the SOC calculation part to delay a change in SOC depending on a load of the battery.

According to still another embodiment of the present disclosure, there is provided a state of charge (SOC) detecting system including a batter pack and a load side system, wherein the battery pack includes: a battery; and a state of charge (SOC) detecting device, wherein the SOC detecting device includes: a voltage monitor part connected to the battery and configured to monitor a voltage of the battery; a current monitor part connected to the battery and configured to monitor a current of the battery; an SOC calculation part configured to calculate an SOC of the battery by using any one or both of a voltage value monitored by the voltage monitor part and a current value monitored by the current monitor part; and an SOC conversion part configured to convert the SOC calculated by the SOC calculation part to delay a change in SOC depending on a load of the battery.

According to still another embodiment of the present disclosure, there is provided a state of charge (SOC) detecting method of a battery to be executed by an SOC detecting device including a voltage monitor part connected to the battery, a current monitor part connected to the battery, an SOC calculation part, and an SOC conversion part, the method including: monitoring a voltage of the battery by the voltage monitor part; monitoring a current of the battery by the current monitor part; calculating, by the SOC calculation part, an SOC of the battery by using any one or both of a voltage value monitored by the voltage monitor part and a current value monitored by the current monitor part; and converting, by the SOC conversion part, the SOC calculated by the SOC calculation part to delay a change in SOC depending on a load of the battery.

### BRIEF DESCRIPTION OF THE DRAWINGS

FIG. 1 is a view illustrating a relationship between an SOC and a discharge time in a comparative example.

FIG. 2 is a schematic block diagram of an SOC detecting system including a battery pack having an SOC detecting device (control IC) according to a comparative example.

FIG. 3 is a schematic block diagram of an SOC detecting system including a battery pack having an SOC detecting device (control IC) according to a first embodiment of the present disclosure.

FIG. 4 is a view illustrating an example of a secondary Bezier curve used in the SOC detecting device according to the first embodiment.

FIG. 5 is a view illustrating another example of a secondary Bezier curve used in the

SOC detecting device according to the first embodiment.

FIG. 6 is a view illustrating a relationship between an SOC and a discharge time in the first embodiment.

FIG. 7 is a schematic flowchart illustrating an example of an SOC detecting method by the SOC detecting device according to the first embodiment.

FIG. 8 is a schematic block diagram of an SOC detecting system including a battery pack having an SOC detecting device (control IC) according to a second embodiment of the present disclosure.

FIG. 9 is a view illustrating a relationship between an SOC and a discharge time in the second embodiment.

FIG. 10 is a schematic flowchart illustrating an example of an SOC detecting method by the SOC detecting device according to the second embodiment.

### DETAILED DESCRIPTION

Hereinafter, embodiments of the present disclosure will be described with reference to the drawings. In the following description of the drawings, like or similar reference numerals are used for like or similar parts. However, it should be noted that the drawings are schematic, and the relationships between thicknesses and planar dimensions, the thickness ratios of respective layers, and the like are different from those of reality. Thus, specific thicknesses or dimensions should be determined in consideration of the following description. Also, it is understood that parts having different dimensional relationships or ratios are included among the drawings.

Further, the embodiments described below are presented to illustrate apparatuses or methods for embodying the technical concept of the present disclosure and are not intended to limit the materials, features, structures, arrangements, and the like of the components to those shown below. The embodiments may be variously modified within the scope of claims.

### COMPARATIVE EXAMPLE

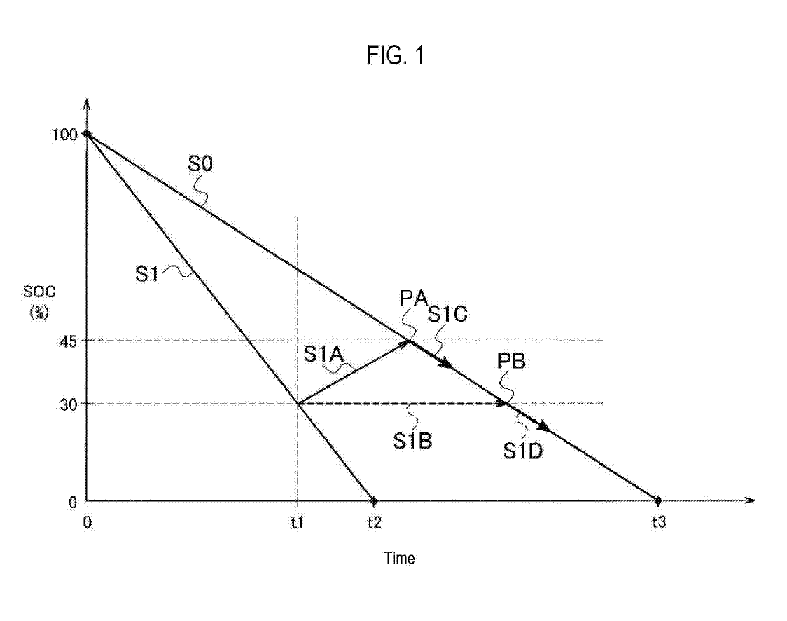

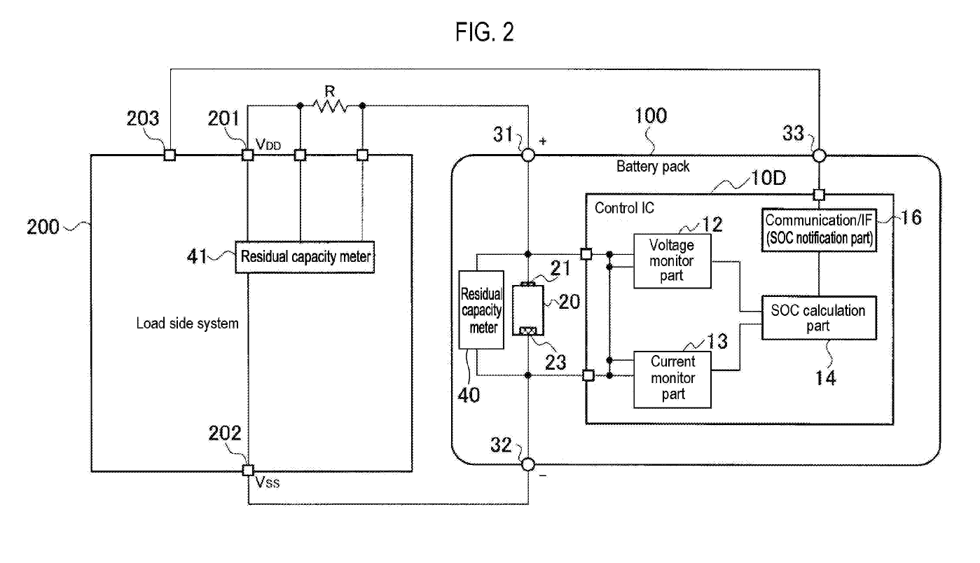

In a comparative example, the relationship between an SOC and a discharge time is illustrated in FIG. 1. Also, a schematic block diagram of an SOC detecting system including a battery pack 100 having an SOC detecting device (control IC) 10D according to the comparative example is illustrated in FIG. 2.

As illustrated in FIG. 2, the SOC detecting system according to the comparative example includes the battery pack 100 and a load-side system 200. The load-side system 200 may be configured as, for example, a smartphone, a mobile phone, or the like. A positive electrode terminal 31 of the battery pack 100 is connected to a positive electrode-side power source terminal 201 (V_{DD}) of the load-side system 200, and a negative electrode terminal 32 of the battery pack 100 is connected to a negative electrode-side power source terminal 202 (V_{SS}) of the load-side system 200. Also, a communication terminal 33 of the battery pack 100 is connected to a communication terminal 203 of the load-side system 200. A residual capacity meter 41 is disposed within the load-side system 200.

The battery pack 100 includes a battery 20, the SOC detecting device 10D, and a residual capacity meter 40 for displaying a residual capacity of the battery. A positive electrode 21 of the battery 20 is connected to the positive electrode terminal 31 of the battery pack 100, and a negative electrode 23 of the battery 20 is connected to the negative electrode terminal 32 of the battery pack 100.

The SOC detecting device 10D includes a voltage monitor part 12, a current monitor part 13, an SOC calculation part 14, and a communication interface (I/F) (SOC notification part) 16. The voltage monitor part 12 is connected to the positive electrode 21 and the negative electrode 23 of the battery 20, and monitors a voltage of the battery 20 and transmits the monitored voltage value to the SOC calculation part 14. The current monitor part 13 is connected to the positive electrode 21 and the negative electrode 23 of the battery 20, and monitors a current of the battery 20 and transmits the monitored current value to the SOC calculation part 14. The SOC calculation part 14 calculates an SOC (a state of charge, i.e., a residual battery capacity) of the battery 20 by using any one or both of the voltage value of the battery 20 received from the voltage monitor part 12 and the current value of the battery 20 received from the current monitor part 13, and transmits the calculated SOC to the SOC notification part 16. The SOC notification part 16 transmits (notifies) the SOC received from the SOC calculation part 14 to any one or both of the residual capacity meter 40 of the battery pack 100 or the residual capacity meter 41 of the load-side system 200. The residual capacity meter 40 or the residual capacity meter 41 visually displays the SOC received from the SOC notification part 16.

The SOC (residual battery capacity) of the battery 20 calculated and notified by the SOC detecting device 10D is illustrated in FIG. 1. In FIG. 1, S0 indicates a case in which a consumed electric charge of a load is relatively small (for example, 0.1 coulomb (C)), and S1 illustrates a case in which a consumed electric charge of a load is relatively large (for example, 0.6 C). When a consumed electric charge of a load is relatively small like S0 (for example, 0.1 C), an SOC is slowly reduced from a fully charged state (100%) to a completely discharged state (0%). Meanwhile, as a consumed electric charge of a load becomes large like S1 (for example, 0.6 C), an SOC is rapidly reduced from the fully charged state to the completely discharged state. That is, in case of S0, the fully charged state is changed to the completely discharged state at time t3, whereas, in case of S1, the fully charged state is changed to the completely discharged state at time t2 earlier than the time t3.

Here, when the electric charge of the load is changed from S1 (0.6 C) to S0 (0.1 C) during discharging (at time t1 in FIG. 1), if there is no internal impedance of the battery 20, the SOC indicates only a residual capacity (i.e., a charge state). In this case, even when the electric charge of the load is reduced at the time t1, the SOC is maintained at 30% (the dotted arrow S1B in FIG. 1), rather than being increased, and reduced at a point PB (the dotted line arrow S1D in FIG. 1). Further, in FIG. 1, the vertical axis represents an SOC, and the horizontal axis represents a discharge time.

However, an internal impedance is actually present in the battery 20, and thus, when a load is high (i.e., when the electric charge of the load is large), a battery voltage is dropped due to a resistance loss based on an internal impedance. Due to the voltage drop, it appears that the capacity of the battery 20 is reduced. That is, when the electric charge of the load is reduced at the time t1, it appears as if the capacity of the battery 20 has been reduced, and thus, as a result, it appears that, for example, an SOC which was 30% has been increased to 45% (the solid line arrow S1A in FIG. 1). When it appears as if the capacity of the battery 20 has been increased in during the discharging, a user may feel a sense of incompatibility, and thus, there is a need to clamp the SOC. However, since the SOC actually follows the solid line arrows S1A→S1C, it appears as if the SOC is not changed (reduced) in spite of being discharged while the SOC is actually clamped (until the SOC reaches the point PB in FIG. 1). Also, when the electric charge of the load is reduced, since the SOC is slowly reduced as mentioned above, the time that the SOC is not changed (not reduced) is increased, and as a result, the SOC reaches a completely discharged state (SOC is 0%) faster than it looks.

### First Embodiment

### (SOC Detecting System)

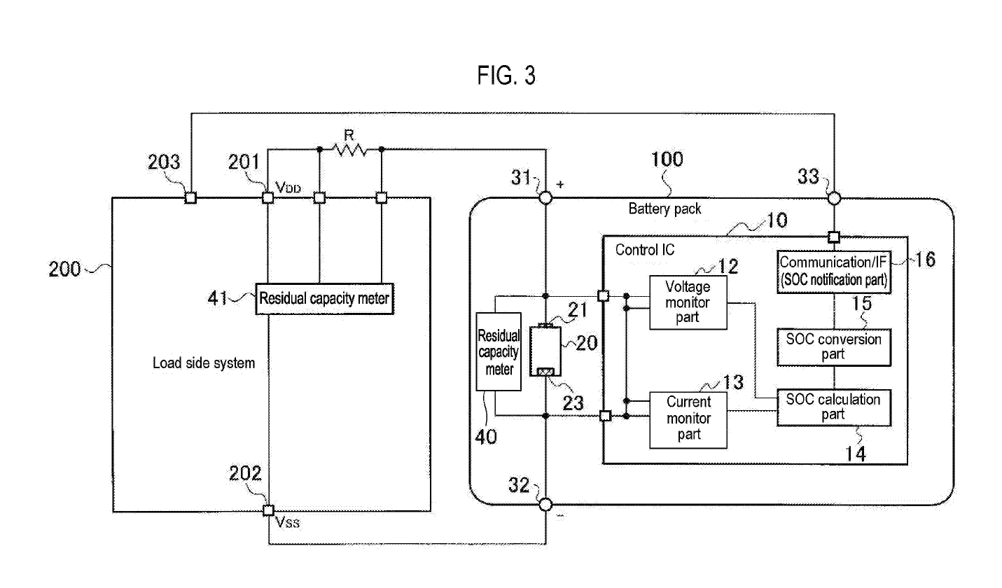

FIG. 3 illustrates an SOC detecting system including a battery pack 100 having an SOC detecting device (control IC) 10 according to a first embodiment of the present disclosure.

As illustrated in FIG. 3, the SOC detecting system according to the first embodiment includes the battery pack 100 and a load-side system 200. The load-side system 200 may be configured as, for example, a smartphone, a mobile phone, or the like. A positive electrode terminal 31 of the battery pack 100 is connected to a positive electrode-side power source terminal 201 (V_{DD}) of the load-side system 200, and a negative electrode terminal 32 of the battery pack 100 is connected to a negative electrode-side power source terminal 202 (V_{SS}) of the load-side system 200. Also, a communication terminal 33 of the battery pack 100 is connected to a communication terminal 203 of the load-side system 200. A residual capacity meter 41 is disposed within the load-side system 200.

### (Battery Pack)

The battery pack 100 includes a battery 20, the SOC detecting device 10, and a residual capacity meter 40 for displaying a battery charge residual capacity. A positive electrode 21 of the battery 20 is connected to the positive electrode terminal 31 of the battery pack 100, and a negative electrode 23 of the battery 20 is connected to the negative electrode terminal 32 of the battery pack 100.

### (SOC Detecting Device)

The SOC detecting device 10 includes a voltage monitor part 12, a current monitor part 13, an SOC calculation part 14, an SOC conversion part 15, and a communication interface (I/F) (SOC notification part) 16. The voltage monitor part 12 is connected to the positive electrode 21 and the negative electrode 23 of the battery 20, and monitors a voltage of the battery 20 and transmits the monitored voltage value to the SOC calculation part 14. The current monitor part 13 is connected to the positive electrode 21 and the negative electrode 23 of the battery 20, and monitors a current of the battery 20 and transmits the monitored current value to the SOC calculation part 14. The SOC calculation part 14 calculates an SOC (a state of charge, i.e., a residual battery capacity) of the battery 20 by using any one or both of the voltage value of the battery 20 received from the voltage monitor part 12 and the current value of the battery 20 received from the current monitor part 13, and transmits the calculated SOC to the SOC conversion part 15. The SOC conversion part 15 performs conversion to delay a change (degree of reduction) in SOC received from the SOC calculation part 14 depending on an electric charge (a quantity of electricity) of the load of the battery 20, and transmits the converted SOC to the SOC notification part 16. The SOC notification part 16 transmits (notifies) the SOC received from the SOC conversion part 15 to any one or both of the residual capacity meter 40 of the battery pack 100 or the residual capacity meter 41 of the load-side system 200. The residual capacity meter 40 or the residual capacity meter 41 visually displays the SOC received from the SOC notification part 16.

### (Secondary Bezier Curve)

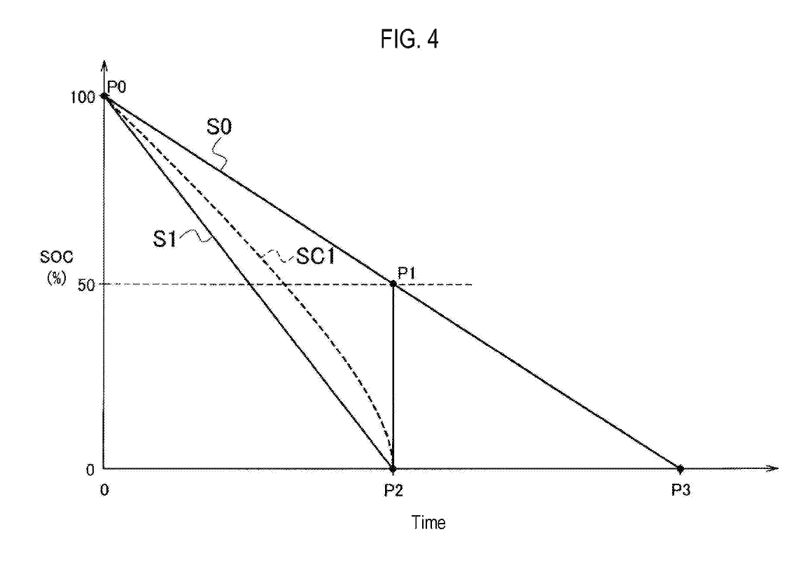

The SOC conversion part 15 may apply, for example, a secondary Bezier curve SC1 as illustrated in FIG. 4 to calculation for delaying the change in SOC depending on the load. In FIG. 4, the vertical axis represents an SOC (residual battery capacity) and the horizontal axis represents a discharge time. In FIG. 4, assuming a case in which an electric charge of the load is changed from S1 (0.6 C) to SO (0.1 C), the secondary Bezier curve SC1 having control points P0, P1, and P2 is applied to delay a change in SOC depending on the load (0.6 C) at S1. P0 is a point at which the SOC is 100% (fully charged state), P2 is an anticipated point at which the SOC is 0% (completely discharged state) at S1, and P1 is an anticipated point at which SOC is 50% (a middle point between the fully charged state and the completely discharged state) at S0. In FIG. 4, the curve SC1 is the secondary Bezier curve generated from the control points P0, P1, and P2.

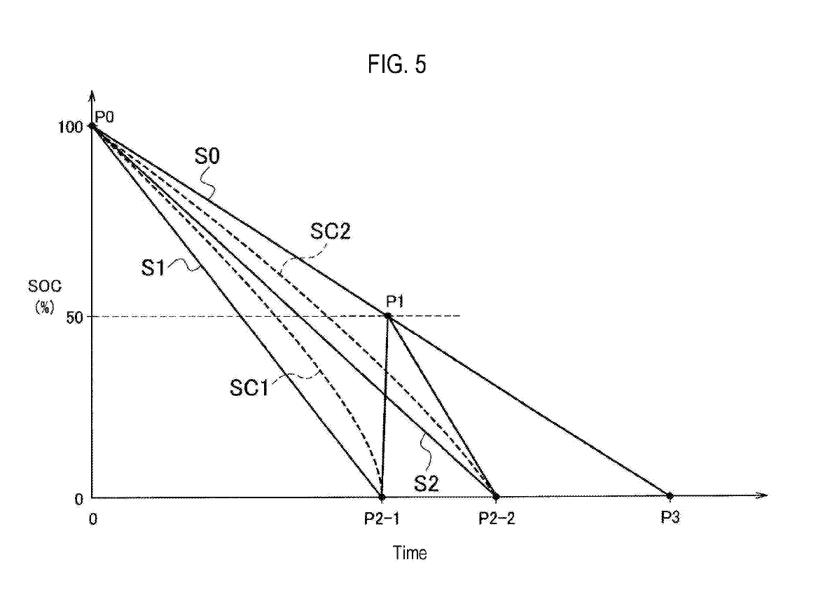

FIG. 5 illustrates another example of a secondary Bezier curve. Like that illustrated in FIG. 4, the curve SC1 is a secondary Bezier curve when the load is 51, and is generated from the control points P0 (fully charged state), P1 (SOC is 50% at S0), and P2-1 (an anticipated point at which the SOC is 0% (completely discharged state) at S1). Also, the curve SC2 is a secondary Bezier curve when the load is S2, and is generated from the control points P0, P1, and P2-1 (an anticipated point at which the SOC is 0% (completely discharged state) at S2).

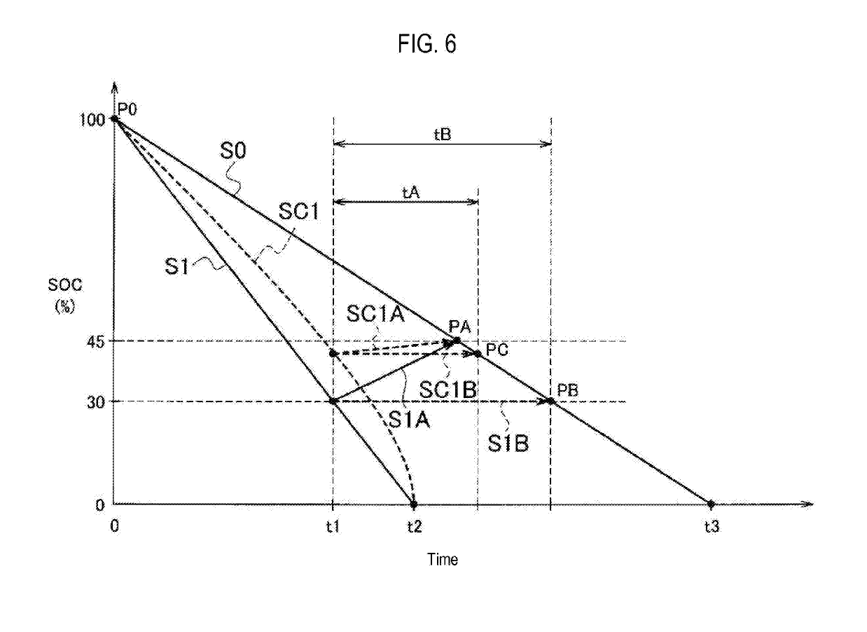

FIG. 6 illustrates an example in which an SOC is converted using the secondary Bezier curve SC1 illustrated in FIG. 4. In a case in which the secondary Bezier curve SC1 is used, trajectory of the SOC when the load is high and when the load is low become close, compared with the case (S1) in which the secondary Bezier curve SC1 is not used. Even when the electric charge of the load is changed from S1 (0.6 C) to S0(0.1 C) at the time t1 and a battery voltage is dropped due to a resistance loss based on an internal impedance of the battery 20, and thus it appears as if the capacity of the battery 20 is reduced, an increase ratio of SOC (a slope angle of the line SC1A with respect to the line SC1B of FIG. 6) when the secondary Bezier curve SC1 is used is less smooth than an increase ratio of SOC (a slope angle of the line S1A with respect to the line S1B of FIG. 6) when the secondary Bezier curve SC1 is not used. Also, since a clamp time to of SOC when the secondary Bezier curve SC1 is used may be shorter than a clamp time tB of SOC when the secondary Bezier curve SC1 is not used (tA<tB), user incompatibility can be reduced.

### (SOC Detecting Method)

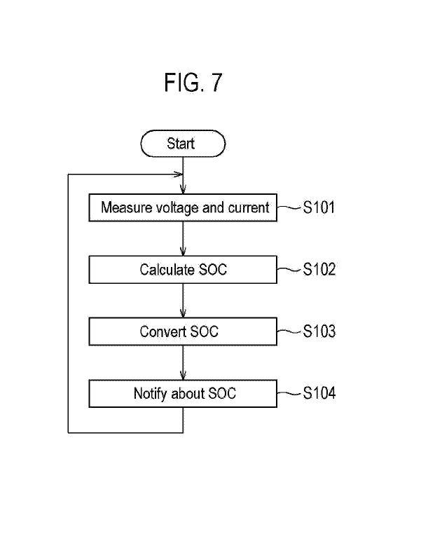

FIG. 7 illustrates an example of an SOC detecting method of the battery 20 by the SOC detecting device 10 according to the first embodiment.

In step S101, the voltage monitor part 12 monitors a voltage of the battery 20 and transmits the monitored voltage value to the SOC calculation part 14. Meanwhile, the current monitor part 13 monitors a discharge current of the battery 20 and transmits the monitored current value to the SOC calculation part 14.

In step S102, the SOC calculation part 14 calculates an SOC of the battery 20 by using any one or both of the voltage value of the battery 20 received from the voltage monitor part 12 and the current value of the battery 20 received from the current monitor part 13, and transmits the calculated SOC to the SOC conversion part 15.

A method for calculating an SOC by the SOC calculation part 14 may include a method for calculating a residual capacity of the battery based on the voltage value of the battery 20 received from the voltage monitor part 12, a method for calculating a residual capacity of the battery, while accumulating the current value (an outflow current value) of the battery 20 received from the current monitor part 13, a combination method thereof, or the like.

In step S103, the SOC conversion part 15 performs conversion to delay a change (degree of reduction) in SOC received from the SOC calculation part 14 by using, for example, the Bezier curve SC1 as illustrated in FIGS. 4 to 6 according to an electric charge (quantity of electricity) of the load, and transmits the converted SOC to the SOC notification part 16.

In step S104, the SOC notification part 16 transmits (notifies) the SOC received from the SOC conversion part 15 to any one or both of the residual capacity meter 40 of the battery pack 100 and the residual capacity meter 41 of the load-side system 200. And, the residual capacity meter 40 or the residual capacity meter 41 visually displays the SOC received from the SOC notification part 16.

According to the first embodiment, even when the electric charge of the load is changed, a smooth SOC with less fluctuation can be detected and notified. Thus, it is possible to avoid a user's sense of incompatibility that the completely discharged state (SOC is 0%) is reached faster than it looks, so that a user friendly SOC can be notified and presented.

### Second Embodiment

### (SOC Detecting System and SOC Detecting Device)

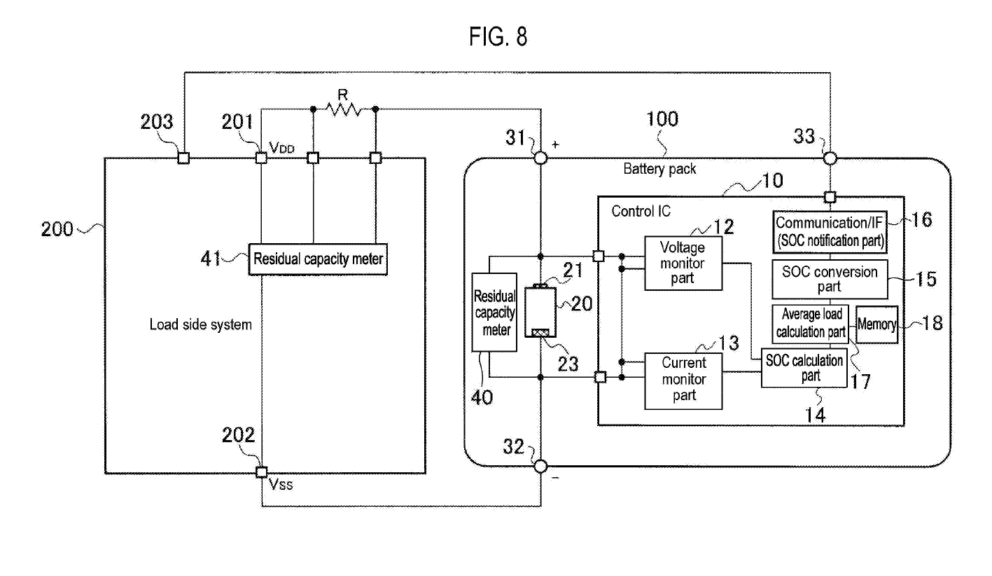

FIG. 8 illustrates an SOC detecting system including a battery pack 100 having an SOC detecting device (control IC) 10 according to a second embodiment of the present disclosure.

In an SOC detecting device 10 according to the second embodiment, an average load calculation part 17 and a memory 18 connected to the average load calculation part 17 are inserted between the SOC calculation part 14 and the SOC notification part 16. Other components are the same as those of the first embodiment.

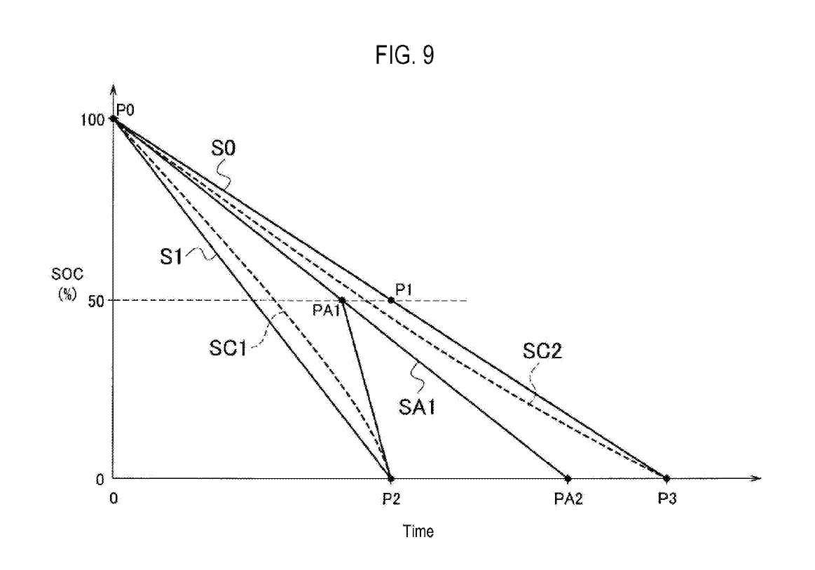

As illustrated in FIG. 9, the SOC detecting device 10 according to the second embodiment generates a second Bezier curve SC1 using a control point PA1 instead of the control point P1. The control point PA1 is an anticipated point at which an SOC is 50% in a load SA1. Here, the load SA1 is average value data calculated and drawn by the average load calculation part 17 based on data stored in the memory 18 by previously measuring (actually measured value) a predetermined load at a predetermined time in the past, and a point at which a completely discharged state is reached is PA2.

The SOC conversion part 15 generates the secondary Bezier curve SC1 based on the control points P0, PA1, and P2 by using the control point PA1 of the average load SA1 calculated by the average load calculation part 17, and converts the SOC received from the SOC calculation part 14 to delay the change of the SOC depending on the electric charge of the load.

Compared with the first embodiment, an effect that an error between the SOC calculated from the secondary Bezier curve SC1 of the second embodiment and an actual SOC is small can be obtained.

### (SOC Detecting Method)

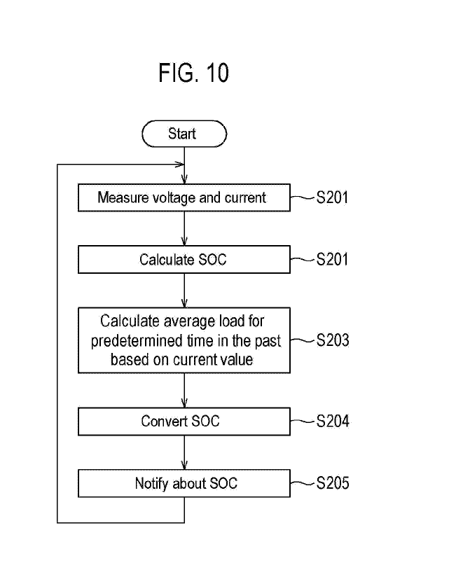

FIG. 10 illustrates an example of an SOC detecting method of the battery 20 by the SOC detecting device 10 according to the second embodiment.

In step S201, the voltage monitor part 12 monitors a voltage of the battery 20 and transmits the monitored voltage value to the SOC calculation part 14. Meanwhile, the current monitor part 13 monitors a discharge current of the battery 20 and transmits the monitored current value to the SOC calculation part 14.

In step S202, the SOC calculation part 14 calculates an SOC of the battery 20 by using any one or both of the voltage value of the battery 20 received from the voltage monitor part 12 and the current value of the battery 20 received from the current monitor part 13, and transmits the calculated SOC to the average load calculation part 17.

In step S203, the average load calculation part 17 calculates average value data based on the actually measured value in the past which was measured in advance and stored in the memory 18, the transmits the calculated average value data together with the SOC received from the SOC calculation part 14 to the SOC conversion part 15.

In step S204, the SOC conversion part 15 generates a secondary Bezier curve SC1, for example, based on the control points P0, PA1, and P2 as illustrated in FIG. 9, converts the SOC received from the SOC calculation part 14 by using the generated Bezier curve SC1 to delay a change (degree of reduction) in SOC depending on an electric charge (quantity of electricity) of the load, and transmits the converted SOC to the SOC notification part 16.

In step S205, the SOC notification part 16 transmits (notifies) the SOC received from the SOC conversion part 15 to any one or both of the residual capacity meter 40 of the battery pack 100 and the residual capacity meter 41 of the load-side system 200. And, the residual capacity meter 40 or the residual capacity meter 41 visually displays the SOC received from the SOC notification part 16.

According to the second embodiment, even when the electric charges of the load are changed, a smooth SOC with less fluctuation can be detected and notified with less error. Thus, it is possible to avoid a user's sense of incompatibility that the completely discharged state (SOC is 0%) is reached faster than it looks, so that a user-friendly SOC can be notified and presented.

As described above, according to this embodiment, it is possible to provide the SOC detecting device, the SOC detecting method, the SOC detecting system, and the battery pack, which are capable of detecting and notifying a smooth SOC with less fluctuation even when the electric charge of the load is changed.

### Other Embodiments

Although the embodiments have been described, the description and drawings constituting part of the present disclosure are merely illustrative and should not be understood to be limiting. Various alternative embodiments, examples, and operating techniques will be apparent to those skilled in the art from the present disclosure.

For example, in the embodiments, the example of using the secondary Bezier curve generated by using three control points is illustrated, but, for example, a tertiary Bezier curve generated by using four control points may be used, or a curve (for example, a curve based on actually measured values in the past) other than the Bezier curve may also be used in the same manner.

Further, in the embodiments, although the calculation of the Bezier curve is applied to the SOC conversion part, the parameters for converting an SOC may be stored in a look-up table or the like to convert the SOC using the same.

Also, in the embodiments, although the case of using a lithium ion battery has been described, the present disclosure may also be applied in the same manner to a battery, for example, a nickel hydrogen battery or the like, other than the lithium ion battery.

Thus, the present disclosure includes various embodiments that are not mentioned herein.

According to the present disclosure in some embodiments, it is possible to provide an SOC detecting device, an SOC detecting method, an SOC detecting system, and a battery pack, which can detect and notify a smooth SOC which fluctuates less even when an electric charge of a load is changed.

The SOC detecting device, the SOC detecting method, the SOC detecting system, and the battery pack according to the present embodiment can be applied to various applications such as a mobile device (for example, a mobile phone, a smartphone, or a game machine) using a battery such as a lithium ion battery as a power source, a power tool, automotive, a power-assisted bicycle, a household battery.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A state of charge (SOC) detecting device, comprising:
a voltage monitor part connected to a battery and configured to monitor a voltage of the battery;
a current monitor part connected to the battery and configured to monitor a current of the battery;
an SOC calculation part configured to calculate an SOC of the battery by using any one or both of a voltage value monitored by the voltage monitor part and a current value monitored by the current monitor part; and
an SOC conversion part configured to convert the SOC calculated by the SOC calculation part to delay a change in SOC depending on a load of the battery.

2. The device of claim 1, further comprising an SOC notification part configured to externally notify about the SOC converted by the SOC conversion part.

3. The device of claim 2, wherein the SOC notification part is configured to notify an external residual capacity meter of the SOC.

4. The device of claim 1, wherein the SOC conversion part is configured to convert the SOC using a predetermined curve.

5. The device of claim 4, wherein the predetermined curve is a Bezier curve.

6. The device of claim 5, wherein the Bezier curve is a secondary Bezier curve generated based on three predetermined control points.

7. The device of claim 6, wherein the three control points comprise:
a point at which the SOC is a fully charged state;
a point at which the SOC is a completely discharged state; and
a middle point between the fully charged state and the completely discharged state in a load lower than the load of the SOC.

8. The device of claim 1, further comprising an average load calculation part configured to calculate an average value data based on a data obtained by previously measuring a predetermined load in the past,
wherein the SOC conversion part is configured to generate a predetermined curve using the average value data, and convert the SOC.

9. The device of claim 6, wherein the predetermined curve is a secondary Bezier curve generated based on a point at which the SOC is a fully charged state, a point at which the SOC is a completely discharged state, and a middle point between an SOC of an average load and the completely discharged state.

10. A battery pack, comprising:
a battery; and
a state of charge (SOC) detecting device,
wherein the SOC detecting device comprises:
a voltage monitor part connected to the battery and configured to monitor a voltage of the battery;
a current monitor part connected to the battery and configured to monitor a current of the battery;
an SOC calculation part configured to calculate an SOC of the battery by using any one or both of a voltage value monitored by the voltage monitor part and a current value monitored by the current monitor part; and
an SOC conversion part configured to convert the SOC calculated by the SOC calculation part to delay a change in SOC depending on a load of the battery.

11. The battery pack of claim 10, wherein the SOC detecting device further comprises an SOC notification part configured to externally notify about the SOC converted by the SOC conversion part.

12. The battery pack of claim 11, wherein the battery pack further comprises a residual capacity meter, and
the SOC notification part is configured to notify the residual capacity meter of the SOC.

13. The battery pack of claim 10, wherein the SOC conversion part is configured to convert the SOC using a predetermined curve.

14. The battery pack of claim 13, wherein the predetermined curve is a Bezier curve.

15. The battery pack of claim 14, wherein the Bezier curve is a secondary Bezier curve generated based on three predetermined control points.

16. The battery pack of claim 15, wherein the three predetermined control points comprise:
a point at which the SOC is a fully charged state;
a point at which the SOC is a completely discharged state; and
a middle point between the fully charged state and the completely discharged state in a load lower than the load of the SOC.

17. The battery pack of claim 10, wherein the SOC detecting device further comprises an average load calculation part configured to calculate average value data based on data obtained by previously measuring a predetermined load in the past, and
the SOC conversion part is configured to generate a predetermined curve using the average value data to convert the SOC.

18. The battery pack of claim 17, wherein the predetermined curve is a secondary Bezier curve generated based on a point at which the SOC is a fully charged state, a point at which the SOC is a completely discharged state, and a middle point between an SOC of an average load and the completely discharged state.

19. A state of charge (SOC) detecting system comprising a battery pack and a load-side system, wherein the battery pack comprises:
a battery; and
a state of charge (SOC) detecting device,
wherein the SOC detecting device comprises:
a voltage monitor part connected to the battery and configured to monitor a voltage of the battery;
a current monitor part connected to the battery and configured to monitor a current of the battery;
an SOC calculation part configured to calculate an SOC of the battery by using any one or both of a voltage value monitored by the voltage monitor part and a current value monitored by the current monitor part; and
an SOC conversion part configured to convert the SOC calculated by the SOC calculation part such to delay a change in SOC depending on a load of the battery.

20. The system of claim 19, wherein the load side system further comprises a residual capacity meter,
the SOC detecting device further comprises an SOC notification part configured to externally notify about the SOC converted by the SOC conversion part, and
the SOC notification part is configured to notify the residual capacity meter of the SOC.

21. The system of claim 20, wherein the SOC conversion part is configured to convert the SOC using a predetermined curve.

22. The system of claim 20, wherein the SOC detecting device further comprises an average load calculation part configured to calculate average value data based on data obtained by previously measuring a predetermined load in the past, and
the SOC conversion part is configured to generate a predetermined curve using the average value data to convert the SOC.

23. A state of charge (SOC) detecting method of a battery to be executed by an SOC detecting device comprising a voltage monitor part connected to the battery, a current monitor part connected to the battery, an SOC calculation part, and an SOC conversion part, the method comprising:
monitoring a voltage of the battery by the voltage monitor part;
monitoring a current of the battery by the current monitor part;
calculating, by the SOC calculation part, an SOC of the battery by using any one or both of a voltage value monitored by the voltage monitor part and a current value monitored by the current monitor part; and
converting, by the SOC conversion part, the SOC calculated by the SOC calculation part to delay a change in SOC depending on a load of the battery.

24. The method of claim 23, wherein the SOC conversion part is configured to convert the SOC using a predetermined curve.

25. The method of claim 23, wherein the SOC detecting device further comprises an average load calculation part configured to calculate average value data based on data obtained by previously measuring a predetermined load in the past, and
the SOC conversion part is configured to generate a predetermined curve using the average value data to convert the SOC.
